(19) United States
(12) Patent Application Publication
(10) Pub. No.: US 2026/0262196 A1
(43) Pub. Date: Sep. 3, 2026

(54) SYSTEMS AND METHODS FOR THERMAL MANAGEMENT

(71) Applicant: Microsoft Technology Licensing, LLC, Redmond, WA (US)

(72) Inventors: Oscar FARIAS MOGUEL, Seattle, WA (US); Erin Elizabeth HURBI, Bozeman, MT (US); Alexis Grace SCHUBERT, Seattle, WA (US); Dennis TRIEU, Calgary (CA)

(21) Appl. No.: 19/194,750

(22) Filed: Apr. 30, 2025

Related U.S. Application Data
(60) Provisional application No. 63/765,133, filed on Feb. 28, 2025.

(51) Int. Cl. H05K 7/20; G06F 1/20; H10W 40/22

(52) U.S. Cl. CPC H05K 7/2039; G06F 1/20; H05K 7/20327; H10W 40/226

(57) ABSTRACT

A device may include a plurality of dissociated unitary cells adjacent to one another. A dissociated unitary cell may include a base supporting a body having at least one sidewall. A dissociated unitary cell may include a top surface. A dissociated unitary cell may include a plurality of fins to direct a cooling fluid through the body in a three-dimensional flow path through the plurality of dissociated unitary cells.

### CROSS-REFERENCE TO RELATED APPLICATIONS

This application claims priority to and the benefit of U.S. Provisional Patent Application No. 63/765,133, filed February 28, 2025, which is hereby incorporated in its entirety.

### BACKGROUND

Thermal management of a multi-core processor, a system-on-chip (SOC), an application specific integrated circuit (ASIC) or other heat-generating electronic component is necessary for stable and reliable operation. Modern electronic components have non-uniform heat profiles, requiring more thermal management capacity in some regions than other regions. Conventional heat sinks provide sufficient thermal management for the peak demands of the component, while having an inefficient amount of capacity for other regions with lower demand.

### SUMMARY

In some aspects, the techniques described herein relate to a heat sink including: a plurality of dissociated unitary cells adjacent to one another, wherein each of the dissociated unitary cells includes a base supporting a body having at least one sidewall; a top surface; and a plurality of fins to direct a cooling fluid through the body in a three-dimensional flow path through the plurality of dissociated unitary cells.

In some aspects, the techniques described herein relate to a method of manufacturing a heat sink, the method including: obtaining a heat profile for a multi-component electronic device; obtaining a catalog of dissociated unitary cell types; selecting an inlet location based on the heat profile; selecting an outlet location based on the heat profile; creating a heat sink design having a continuous three-dimensional flow path including a plurality of dissociated unitary cells selected from the catalog of dissociated unitary cell types, wherein the plurality of dissociated unitary cells includes at least two different dissociated unitary cell types; and forming a heat sink based on the heat sink design.

This summary is provided to introduce a selection of concepts that are further described below in the detailed description. This summary is not intended to identify key or essential features of the claimed subject matter, nor is it intended to be used as an aid in limiting the scope of the claimed subject matter.

Additional features and aspects of embodiments of the disclosure will be set forth in the description which follows, and in part will be obvious from the description, or may be learned by the practice of such embodiments. The features and aspects of such embodiments may be realized and obtained by means of the instruments and combinations particularly pointed out in the appended claims. These and other features will become more fully apparent from the following description and appended claims or may be learned by the practice of such embodiments as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, non-schematic drawings should be considered as being to scale for some embodiments of the present disclosure, but not to scale for other embodiments contemplated herein. Understanding that the drawings depict some example embodiments, the embodiments will be described and explained with additional specificity and detail through the use of the accompanying drawings in which:

FIG. 1 is a plan view of a computer chip including a plurality of components with a non- uniform heat profile during operation, according to at least some embodiments of the present disclosure.

FIG. 2-1 is a plan view of a heat sink having a plurality of dissociated unitary cells configured to control flow a fluid through the heat sink, according to at least some embodiments of the present disclosure.

FIG. 2-2 is a plan view of a heat sink having a plurality of dissociated unitary cells of various aspect ratios configured to control flow a fluid through the heat sink, according to at least some embodiments of the present disclosure.

FIG. 3-1 is a perspective view of a straight orientation dissociated unitary cell, according to at least some embodiments of the present disclosure.

FIG. 3-2 is a perspective view of the dissociated unitary cell of FIG. 3-1 with a sidewall removed.

FIG. 3-3 is a perspective cross-sectional view of the dissociated unitary cell of FIG. 3-1 showing crossflow proximate a base of the cell.

FIG. 4 is a side cross-sectional view of two straight orientation dissociated unitary cells adjacent to one another in a heat sink and creating a three-dimensional flow path therebetween, according to at least some embodiments of the present disclosure.

FIG. 5-1 is a perspective view of a 90° turn dissociated unitary cell, according to at least some embodiments of the present disclosure.

FIG. 5-2 is a perspective cross-sectional view of the dissociated unitary cell of FIG. 5-1, according to at least some embodiments of the present disclosure.

FIG. 6-1 is a perspective view of a direct impingement dissociated unitary cell, according to at least some embodiments of the present disclosure.

FIG. 6-2 is a perspective cross-sectional view of the dissociated unitary cell of FIG. 6-1, according to at least some embodiments of the present disclosure.

FIG. 7-1 is a perspective view of a T-junction dissociated unitary cell, according to at least some embodiments of the present disclosure.

FIG. 7-2 is a perspective cross-sectional view of the dissociated unitary cell of FIG. 7-1, according to at least some embodiments of the present disclosure.

FIG. 8-1 is a perspective view of a mixing promotion dissociated unitary cell, according to at least some embodiments of the present disclosure.

FIG. 8-2 is a wireframe view of the dissociated unitary cell of FIG. 8-1, according to at least some embodiments of the present disclosure.

FIG. 9 is a cross-sectional plan view of an exemplary heat sink comprising at least some of the dissociated unitary cells described herein, according to at least some embodiments of the present disclosure.

FIG. 10 is a plan view of a hybrid heat sink including a plurality of dissociated unitary cells in a non-cellular frame, according to at least some embodiments of the present disclosure.

FIG. 11 is a method of manufacturing a heat sink, according to at least some embodiments of the present disclosure.

FIG. 12 is a perspective exploded view a heat sink and manifold configured to circulate a working fluid through the heat sink, according to at least some embodiments of the present disclosure.

### DETAILED DESCRIPTION

The present disclosure relates generally to thermal management devices. More particularly, the present disclosure relates to thermal management devices including a plurality of dissociated unitary cells. In some embodiments, a heat sink includes or is made of a plurality of dissociated unitary cells selected from a set of different dissociated unitary cell types to create a fluid flow path in three-dimensions (e.g., x-, y-, and z-directions) through the heat sink. Each of the dissociated unitary cell types includes compatible openings or apertures to allow fluid flow therebetween. By forming a heat sink from dissociated unitary cells selected from the set, the resulting heat sink will have a continuous three-dimensional (3D) flow path that distributes heat through the heat sink with a calculatable pressure drop and predictable compatibility.

In some embodiments, at least one of the physical dissociated unitary cells is formed prior to assembly of the heat sink, and the physical dissociated unitary cells are welded, adhered, or otherwise bound together. In some embodiments, the heat sink is designed based on a plurality of dissociated unitary cells, and the heat sink is manufactured as a monolithic element. For example, the heat sink may have a design that includes a plurality of dissociated unitary cells, and the heat sink is additive manufactured according to the design. In some embodiments, the plurality of dissociated unitary cells are coupled to a non-cellular frame in the heat sink. For example, a first portion of the heat sink includes a plurality of dissociated unitary cells, and a second portion of the heat sink is designed without a plurality of dissociated unitary cells.

In some embodiments, a thermal management device includes a heat sink according to the present disclosure and further includes a manifold configured to deliver a cold working fluid to the heat sink. In some embodiments, the manifold is further configured to receive a hot working fluid from an outlet of the heat sink to recirculate the working fluid after cooling the hot working fluid at a heat exchanger. In some embodiments, the manifold is configured to deliver the cold working fluid at an inlet into the heat sink and receive the hot working fluid at an outlet of the heat sink. The heat sink may be designed from the plurality of dissociated unitary cells based at least partially on a manifold. In some embodiments, the manifold is designed based at least partially on the known positions and dimensions of the inlets and outlets that are possible based on the finite quantity of positions and dimensions possible with the plurality of dissociated unitary cells. Therefore, a heat sink formed from a plurality of dissociated unitary cells may provide benefits to efficiency in design and manufacturing of the heat sink, a manifold for the heat sink, and other associated components.

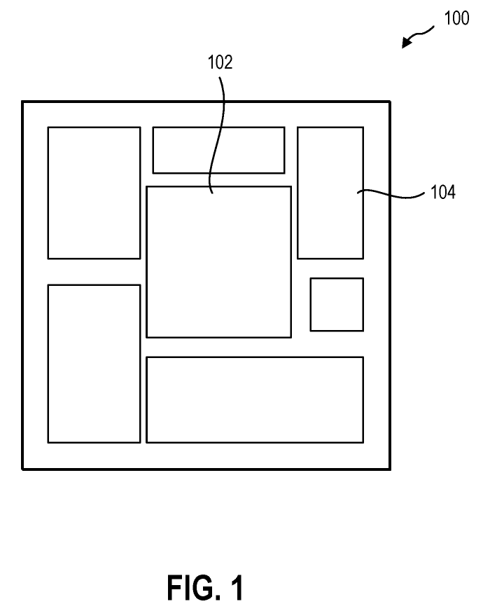

FIG. 1 is a plan view of an embodiment of a computer chip 100 including a plurality of components with a non-uniform heat profile during operation, according to at least some embodiments of the present disclosure. While a computer chip 100 is described herein, the electronic device may be a multi-core processor, a system-on-chip (SOC), an application specific integrated circuit (ASIC), or another heat-generating electronic component. In the illustrated embodiment of FIG. 1, the computer chip 100 includes a processing core 102 and a plurality of subcomponents 104 positioned proximate to and around the processing core 102.

In some embodiments, the processing core 102 generates a different quantity of heat than the subcomponent 104. In some embodiments, the subcomponents 104 generate different quantities of heat relative to one another. The relative production of heat by (and the relative to locations of) the core 102, the subcomponents 104, or other parts of the electronic device define a non-uniform heat profile of the computer chip 100 that requires non-uniform thermal management by a heat sink attached thereto. The area of the computer chip 100 (or any other heat-generating electronic component) may be divided into a plurality of subareas from which a heat sink may be designed.

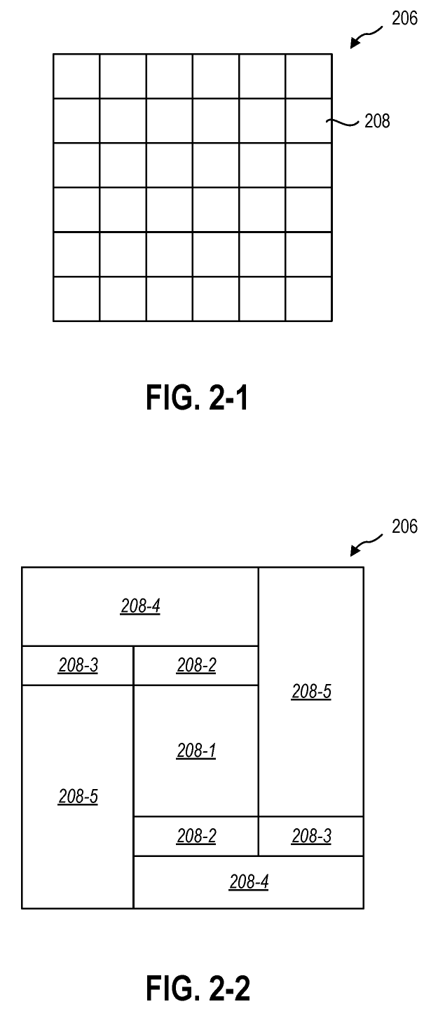

FIG. 2-1 is a plan view of a heat sink 206 having a plurality of dissociated unitary cells 208 configured to control flow a working fluid through the heat sink 206, according to at least some embodiments of the present disclosure. For example, the heat sink 206 of FIG. 2-1 may be configured to cool the embodiment of a computer chip 100 described in relation to FIG. 1. The plurality of dissociated unitary cells 208 are selected from a catalog of known dissociated unitary cell types and/or designs to direct a working fluid flow through the heat sink 206 and dissipate heat from the computer chip or other heat-generating electronic component. In some embodiments, all of the dissociated unitary cells 208 of the heat sink 206 have a uniform shape in the plane of the heat sink 206. For example, each of the dissociated unitary cells 208 may be a square in footprint with each having an equal area and equal dimensions. In other examples, each of the dissociated unitary cells 208 may be a rectangle with an equal area and equal lengths and widths.

The smaller the subareas defined by the dissociated unitary cells 208 relative to the total area of the heat sink 206, the higher resolution the heat sink 206 becomes. In some embodiments, the heat sink 206 includes at least 4 dissociated unitary cells 208 in a first direction. In some embodiments, the heat sink 206 includes at least 4 dissociated unitary cells 208 in a second direction orthogonal to the first direction in the plane of the heat sink 206. In some embodiments, the heat sink 206 includes at least a 4x4 grid with 16 dissociated unitary cells 208. In some embodiments, the heat sink 206 includes at least a 6x6 grid with 24 dissociated unitary cells 208. (It should be understood that a 6x8 grid includes, defined therein, at least a 6x6 grid.) In some embodiments, the heat sink 206 includes a 10x10 grid with 100 dissociated unitary cells 208. For example, a 25mm x 25mm heat sink with 100 dissociated unitary cells 208 includes dissociated unitary cells 208 that are each 2.5mm square.

While heat sinks 206 and dissociated unitary cells 208 described and illustrated herein may be substantially rectilinear or square, it should be understood that other shapes relative to the plane of the heat sink may be used. For example, the heat sink 206 may be square, and each dissociated unitary cell 208 may be square. In another example, the heat sink 206 may be hexagonal, and each dissociated unitary cell 208 may be hexagonal. In yet another example, the heat sink 206 may be hexagonal, and each dissociated unitary cell 208 may be triangular. In some embodiments, the heat sink 206 is any shape needed to match a heat-generating electronic component and/or heat profile. In some embodiments, the dissociated unitary cells 208 are any shape that tessellates. In some embodiments, the dissociated unitary cells 208 are any combination of shapes that tessellates. FIG. 2-2 is a plan view of another embodiment of the heat sink 206 having a plurality of dissociated unitary cells 208 configured to control flow a working fluid through the heat sink 206, according to at least some embodiments of the present disclosure. In some embodiments, the dissociated unitary cells 208 are non-square and/or include a plurality of different aspect ratios. For example, the dissociated unitary cells 208 may be comprised of a different sizes, shapes, or aspect ratios, such as the first dissociated unitary cell 208-1 that is substantially square and the second dissociated unitary cells 208-2, the third dissociated unitary cells 208-3, the fourth dissociated unitary cells 208-4, and the fifth dissociated unitary cells 208-5 that are each rectangular but have different aspect ratios and different areas.

The dissociated unitary cells according to the present disclosure each have a shared open space proximate to a top surface that allows fluid flow between each of the dissociated unitary cells. The dissociated unitary cells each further direct fluid through a body of the cell and/or out of the cell in different directions to control the 3D flow path of the working fluid through the heat sink.

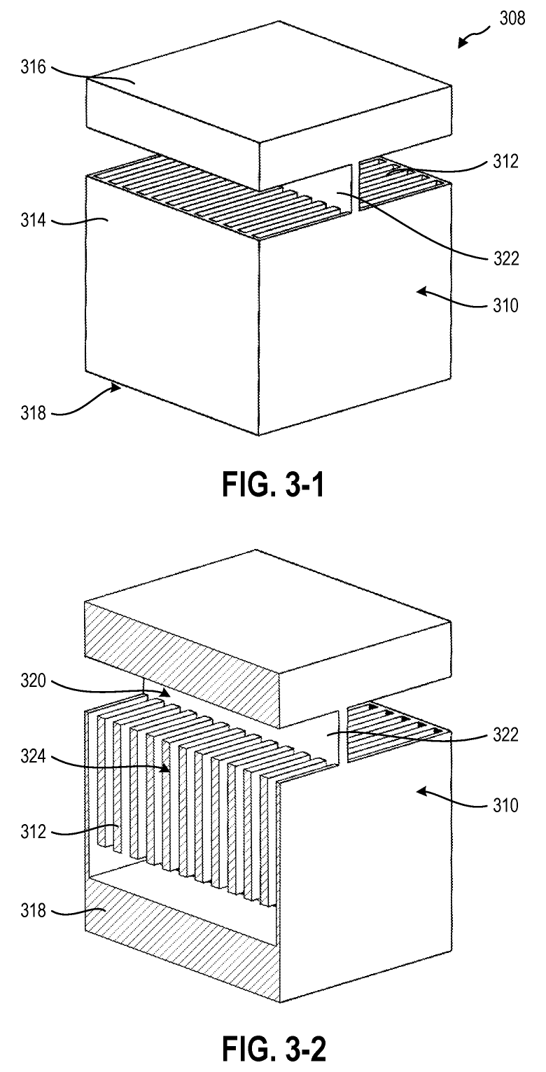

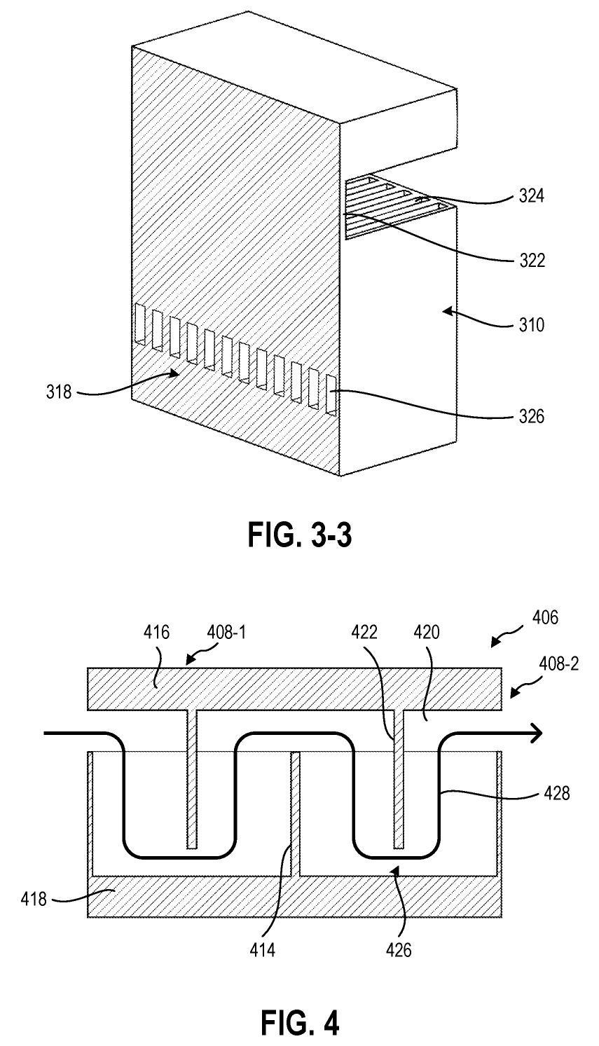

FIG. 3-1 is a perspective view of a straight orientation dissociated unitary cell 308, according to at least some embodiments of the present disclosure. The dissociated unitary cell 308 includes a body 310 with a plurality of fins 312 therein. The fins 312 direct a working fluid therebetween while increasing surface area for conduction of heat to the working fluid. The fluid path of the working fluid in the dissociated unitary cell 308 is at least partially constrained by the sidewalls 314 of the body 310, a top surface 316 of the body 310, and a base 318 of the body 310. An open space 320 proximate to the top surface 316 allows fluid flow over the sidewall 314 and provides fluid communication between dissociated unitary cells 308, as will be described in relation to FIG. 4. In some embodiments, a top surface support 322 extends into the open space 320 and impairs the fluid flow, with the top surface 316 and the top surface support 322 directing the flow path downward away from the top surface 316 and toward the base 318 through the slots 324 between the fins 312, such as illustrated in FIG. 3-2. FIG. 3-2 is a partial cross-sectional view of the embodiment of a dissociated unitary cell 308 illustrated in FIG. 3-1 with the sidewall 314 removed. In some embodiments, heat is received through the base 318 of the dissociated unitary cell 308 and conducted to the working fluid in the slots 324 by the fins 312.

FIG. 3-3 is a cross-sectional view of the embodiment of a dissociated unitary cell 308 illustrated in FIG. 3-1 through the top surface support 322 in the approximate center of the body 310. As the top surface support 322 impairs the lateral fluid flow, the top surface support 322 includes one or more apertures 326 proximate to the base 318, allowing the working fluid to cross the top surface support 322 and flow up through the slots 324 on the opposite side of the top surface support 322. The flow path through the straight orientation dissociated unitary cell 308, therefore, directs the working fluid downward from the open space 320 between the fins 312 toward the base 318, through the aperture(s) 326, and back up through slots 324 between fins 312 on the opposite side. Such a 3D flow path increases the surface area of the dissociated unitary cell 308 in contact with the working fluid and increases the residence time of the working fluid in contact with the fins 312 to transfer heat to the working fluid. A convoluted 3D flow path can further control the pressure drop across each of the dissociated unitary cells 308, providing predictable flow rates through the heat sink as a whole.

FIG. 4 is a side cross-sectional view of two straight orientation dissociated unitary cells 408-1, 408-2 adjacent to one another in a heat sink 406 and creating a 3D flow path 428 therebetween, according to at least some embodiments of the present disclosure. While the cross- sectional view of FIG. 3-3 illustrated a transverse cross-sectional view relative to the flow direction of the 3D flow path 428, FIG. 4 illustrates a longitudinal cross-sectional view relative to the flow direction between fins of the dissociated unitary cells 408-1, 408-2.

In some embodiments, the 3D flow path 428 enters the first dissociated unitary cell 408-1 at the open space 420 proximate to the top surface 416. The 3D flow path 428 is directed downward by the top surface support 422 and the top surface 416 toward the base 418 and through the aperture(s) 426 proximate to the base 418. In some embodiments, a sidewall 414 of the dissociated unitary cell 408-1 then directs the 3D flow path away from the base 418 toward the open space 420.

The 3D flow path 428 then enters the open space 420 of the second dissociated unitary cell 408-2. The 3D flow path 428 is directed downward by the top surface support 422 and the top surface 416 toward the base 418 and through the aperture(s) 426 proximate to the base 418 of the second dissociated unitary cell 408-2. In some embodiments, a sidewall 414 of the second dissociated unitary cell 408-2 then directs the 3D flow path away from the base 418 toward the open space 420. In some embodiments, a dissociated unitary cell 408-1, 408-2 lacks a sidewall on at least one lateral side, allowing fluid communication into the body of the dissociated unitary cell 408-1, 408-2 without forcing the 3D flow path 428 to return to the open space 420. For example, a square dissociated unitary cell may have less than 4 sidewalls.

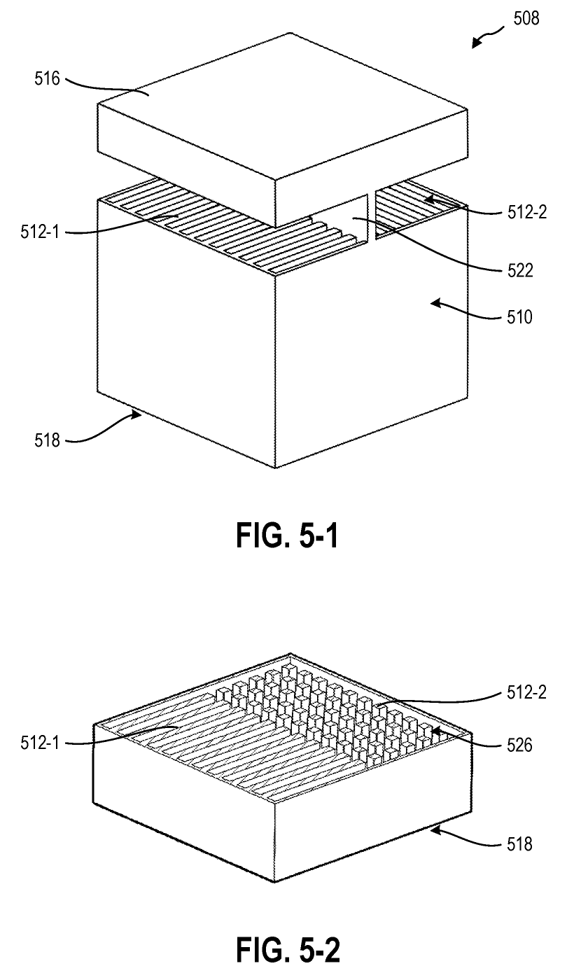

Additional dissociated unitary cell types are presented in FIG. 5-1 through FIG. 8-2 that may be used to control the direction and flow rates of a 3D flow path through a heat sink. FIG. 5- 1 is a perspective view of a 90° turn dissociated unitary cell 508, according to at least some embodiments of the present disclosure. While a dissociated unitary cell 508 with a 90° turn in the flow path is described in relation to FIG. 5-1 and 5-2, in other embodiments, a dissociated unitary cell may turn the flow path by other amounts.

The dissociated unitary cell 508 includes a body 510 with a first plurality of fins 512-1 therein on a first side of a top surface support 522 and a second plurality of fins 512-2 therein on a second side of the top surface support 522. The fins 512-1, 512-2 direct a working fluid therebetween while increasing surface area for conduction of heat to the working fluid. In some embodiments, a top surface support 522 impairs the fluid flow, with the top surface 516 and the top surface support 522 directing the flow path downward away from the top surface 516 and toward the base 518 through the slots between the first plurality of fins 512-1. The second plurality of fins 512-2 on the second side to the top surface support 522 are oriented orthogonally to the first plurality of fins 512-1.

FIG. 5-2 is a perspective cross-sectional view of the dissociated unitary cell 508 of FIG. 5- 1. The 3D flow path flows from between the first plurality of fins 512-1 and through a plurality of apertures 526 proximate to the base 518 in the second plurality of fins 512-2 on the second side of the top surface support. The apertures 526 are located proximate to the base 518 and the second plurality of fins 512-2 become solid fins orthogonal to the first plurality of fins 512-2 as the working fluid flow upward (as illustrated in FIG. 5-1).

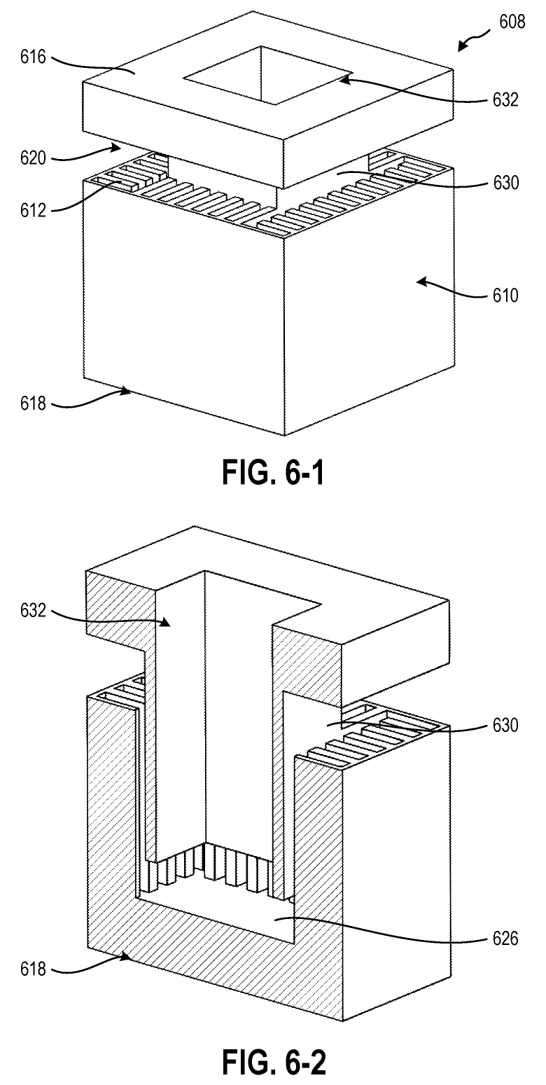

FIG. 6-1 is a perspective view of a direct impingement dissociated unitary cell 608, according to at least some embodiments of the present disclosure. The direct impingement dissociated unitary cell 608 has a body 610 with a central column 630 therein. In some embodiments, the top surface 616 has an inlet 632 into the central column 630 to receive working fluid and direct the working fluid downward toward the base 618.

FIG. 6-2 is a perspective cross-sectional view of the dissociated unitary cell of FIG. 6-1. Cold working fluid from a manifold or other working fluid source directly impinges upon the base 618 of the body 610 at the bottom of the column 630, and the flow path then flows through apertures 626 and upward between fins 612 around the exterior of the column 630 toward the open space 620. From the open space 620, the flow path can continue through the open space of adjacent dissociated unitary cells.

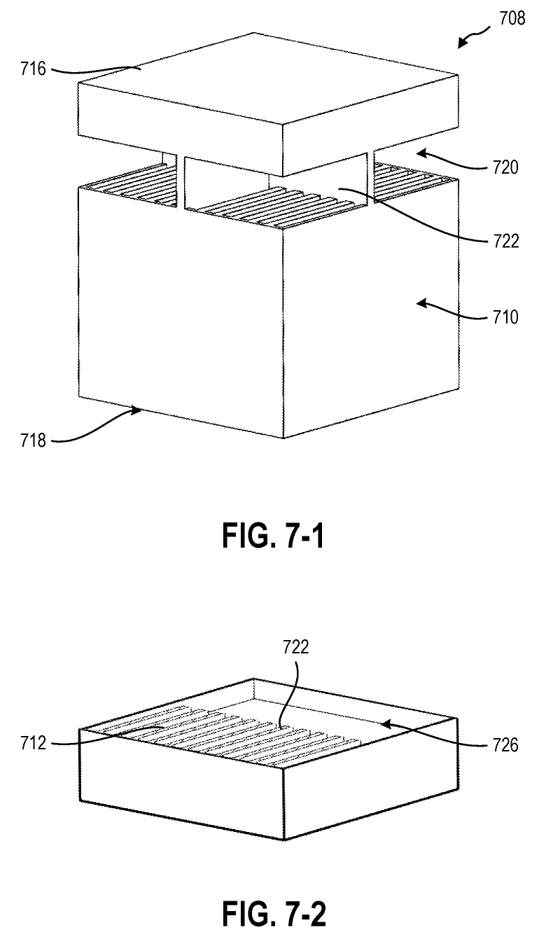

FIG. 7-1 is a perspective view of a T-junction dissociated unitary cell 708 with a T-shaped top surface support 722, according to at least some embodiments of the present disclosure. In some embodiments, the dissociated unitary cell 708 has a body 710 including fins 712 that extend between an open space 720 and a base 718. The top surface 716 confines the flow path and directs the flow path downward toward the base 718. The T-shaped top surface support 722, in some embodiments, keeps the fluid flow separated entering or exiting the slots between the fins 712.

FIG. 7-2 is a perspective cross-sectional view of the dissociated unitary cell 708 of FIG. 7- 1. In some embodiments, the aperture 726 proximate to the base 718 allows mixing of the working fluid exiting the fins 712 at the bottom of the top surface support 722. In some embodiments, the T-junction dissociated unitary cell 708 is configured to collect two different fluid streams coming from two directions in a single outlet and/or vice versa, separating a single stream into two. In some embodiments, the aperture 726 provides a mixing space that is an stratification chamber. In some embodiments, any potential difference in flowrate of working fluid therethrough equalize and a more even distribution across all the channels of the exit route is achieved.

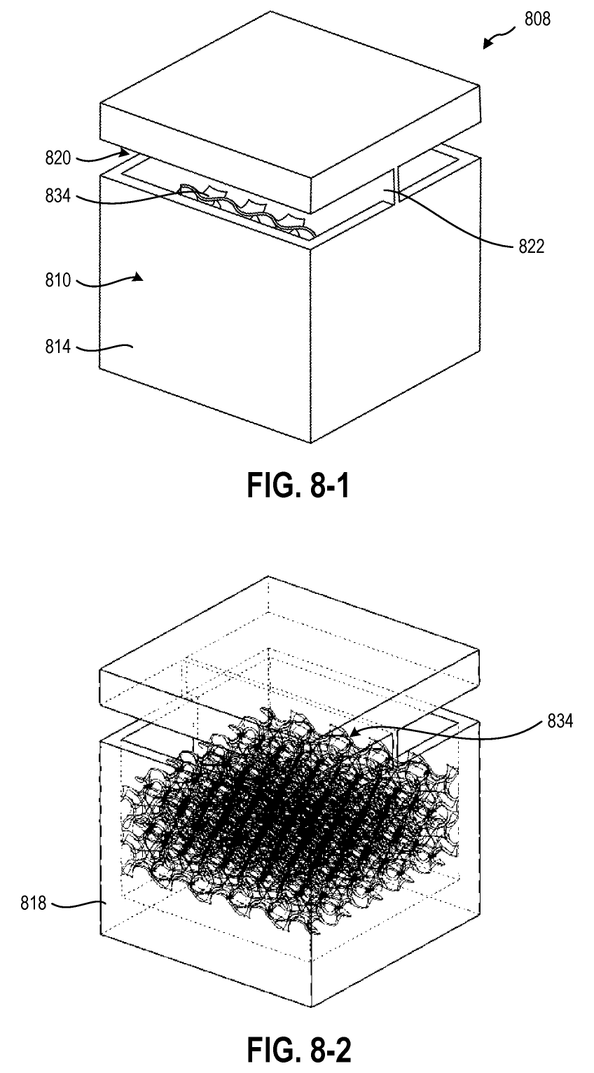

In some embodiments, the dissociated unitary cell does not change a direction of the fluid flow, but rather promotes mixing of the working fluid to distribute heat within the working fluid from the base. FIG. 8-1 is a perspective view of a mixing promotion dissociated unitary cell 808, according to at least some embodiments of the present disclosure. In some embodiments, the body 810 defines an open space 820 that allows working fluid to follow the flow path into an interior volume of the body 810 at least partially defined by sidewalls 814. The flow path flows through the interior volume and under the top surface support 822, as described in relation to other dissociated unitary cell types herein. As the working fluid flows through the interior volume, the flow path through the mixing promotion dissociated unitary cell 808 encounters one or more mixing structures 834, as illustrated in the wireframe view of FIG. 8-2 of the dissociated unitary cell of FIG. 8-1. In some embodiments, the mixing structure 834 is a lattice structure that allows fluid flow therethrough. In some embodiments, the mixture structure 834 is a triply periodic minimal surface (TPMS) including curved surfaces. In some embodiments, the mixture structure 834 is gyroid TPMS including curved surfaces. In some embodiments, the mixing structures 834 has at least 40% porosity (where at least 40% of the lattice volume is empty space to allow fluid flow therethrough). In some embodiments, the mixing structures 834 has at least 80% porosity. In some embodiments, the mixing structures 834 has at least 60% porosity. In some embodiments, the mixing structures 834 has at least 90% porosity. In some embodiments, the mixing structures 834 has at least 95% porosity. In some embodiments, greater porosity allows a greater flow rate therethrough. In some embodiments, the mixing structures 834 also conducts heat into the working fluid, and a lower porosity and greater mass of material allows for more surface area to transfer heat to the working fluid. In some embodiments, the porosity of the mixing structure 834 is substantially uniform throughout the mixing structure 834. In some embodiments, the porosity of the mixing structure 834 varies in a gradient through the mixing structure 834. For example, the porosity may change in a vertical direction (e.g., toward the base 818 or away from the base 818). In other examples, the porosity may change in the flow direction, such as increasing porosity in the flow direction. In such an example, an initially lower porosity (e.g., a higher density of surfaces) in the mixing structure 834 may induce turbulent flow in the working fluid that may propagate in the flow even as the porosity increases and the quantity of mixing surfaces decreases in the flow direction of the 3D flow path.

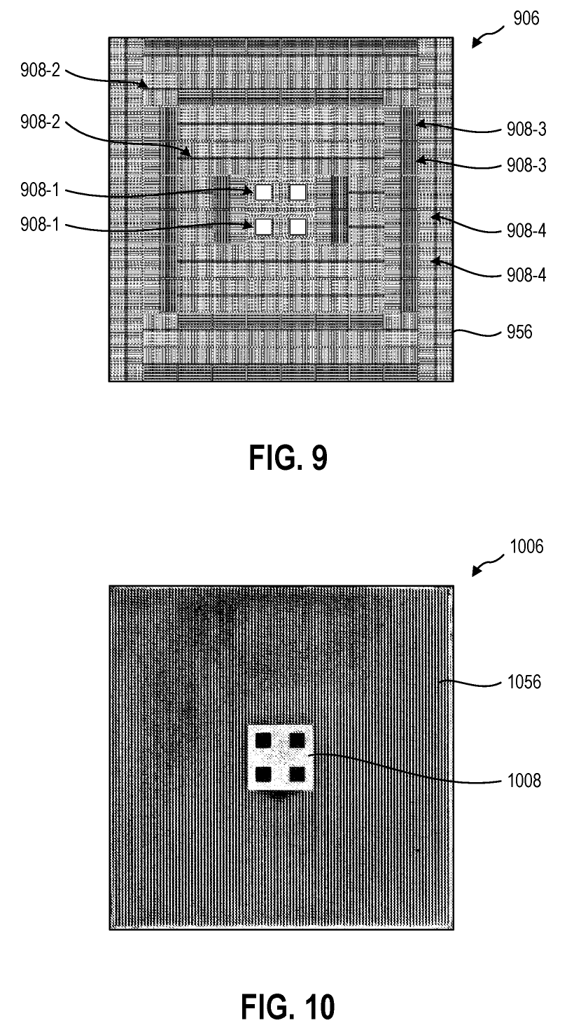

As described herein, a heat sink may include a plurality of dissociated unitary cell types in a single heat sink with at least two dissociated unitary cells adjacent to one another. In some embodiments, the entire heat sink is formed of dissociated unitary cells. FIG. 9 is a cross-sectional plan view of an exemplary heat sink 906 comprising at least some of the dissociated unitary cells 908-1, 908-2, 908-3, 908-4 described herein, according to at least some embodiments of the present disclosure. FIG. 9 illustrates the embodiment of a heat sink 906 with the top surface(s) removed such that the fins and supports are visible to show the direction of the 3D flow path in the heat sink 906. The flow path begins at the direct impingement dissociated unitary cells 908-1 at the center of the heat sink 906 and flows outward toward T-junction dissociated unitary cells 908-2 and then to 90° turn dissociated unitary cells 908-3 and finally through straight orientation dissociated unitary cells 908-4. Cold working fluid is provided to the inlets at the direct impingement dissociated unitary cells 908-1 to cool the hottest portion of the heat profile, and after receiving heat from heat-generating electronic component in contact with the heat sink 906, the straight orientation dissociated unitary cells 908-4 carry the hot working fluid to lateral outlets 956 on the lateral sides of the heat sink 906. The heat sink 906 is entirely formed of dissociated unitary cell types described herein, and allows for a known pressure drop and flow rate through each of the dissociated unitary cells 908-1, 908-2, 908-3, 908-4.

In some embodiments, a heat sink includes a first portion that includes a plurality of dissociated unitary cells and a second portion that is non-cellular. FIG. 10 is a plan view of a hybrid heat sink 1006 including a plurality of dissociated unitary cells 1008 in a non-cellular frame 1036, according to at least some embodiments of the present disclosure. The heat sink 1006 includes a plurality of direct impingement dissociated unitary cells 1008 adjacent to one another in a center of the heat sink 1006. For example, the direct impingement dissociated unitary cells 1008 may receive a cold working fluid, such as described in relation to FIG. 9, to provide the greatest cooling rates to the hottest portion of the heat profile. As described in relation to FIG. 6-1 and 6-2, working fluid that is delivered through inlets (such as the inlets 632 described in relation to FIG. 6-1) into the direct impingement dissociated unitary cells 1008 may flow radially outward through the open space of the direct impingement dissociated unitary cells 1008 and across the fin pack of the non- cellular frame 1036.

In some embodiments, a non-cellular frame 1036 or a non-cellular portion of the heat sink 1006 is a region that include heat transfer elements, such as fins, pins, heat pipes, vapor chambers, etc. that does not include a plurality of dissociated unitary cells. For example, the non-cellular frame 1036 includes a substantially uniform fin pack that, while possible to divide into equal areas, does not include a plurality of dissociated unitary cell types tiled together.

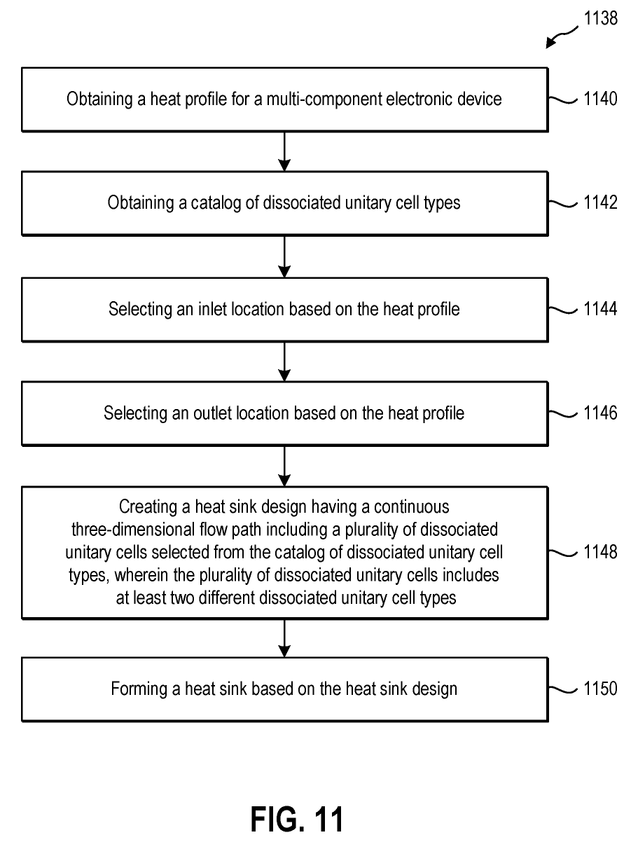

As describe herein, a set or catalog of dissociated unitary cell types can provide a selection of components that each have known thermal conductivity, pressure drops, flowrates, and other thermal properties relevant to heat sink design that can simplify the design of custom heat sinks for the growing number of designs of computer chips and other heat-generating electronic components. FIG. 11 is a method 1138 of manufacturing a heat sink, according to at least some embodiments of the present disclosure. In some embodiments, the method 1138 includes obtaining a heat profile for a multi-component electronic device at 1140. In some embodiments, obtaining the heat profile includes directly measuring the heat profile while the multi-component electronic device is under operational load. In some embodiments, obtaining the heat profile includes simulating the heat profile of the multi-component electronic device under operational load. In some embodiments, obtaining the heat profile includes measuring and/or simulating a plurality of heat profiles under different operational loads (such as a CPU-intensive task and a GPU-intensive task) and averaging the heat profiles together. In some embodiments, obtaining the heat profile includes measuring and/or simulating a plurality of heat profiles under different operational loads (such as a CPU-intensive task and a GPU-intensive task) and selecting the peak temperature of different regions of the heat profiles to aggregate a peak temperature heat profile. In at least one embodiment, obtaining the heat profile includes receiving a specified heat profile from a manufacturer. In some embodiments, the heat profile is defined as a plurality of subareas that correspond to the area of the dissociated unitary cells. For example, a heat profile may have a subarea resolution that is equal to a dissociated unitary cell resolution of the heat sink to be designed. In some examples, the heat profile has a subarea resolution that is greater than (e.g., more measurement points) than the dissociated unitary cell resolution of the heat sink to be designed.

The method 1138 further includes, obtaining a catalog of dissociated unitary cell types at 1142. In some embodiments, the catalog includes a plurality of dissociated unitary cell types. In some embodiments, the catalog includes at least 4 dissociated unitary cell types. In some embodiments, the catalog includes at least two dissociated unitary cell types selected from a straight orientation dissociated unitary cell, a direct impingement dissociated unitary cell, a turn dissociated unitary cell, a T-junction dissociated unitary cell, and a mixing promotion dissociated unitary cell.

The method 1138 further includes selecting an inlet location based on the heat profile at 1144 and selecting an outlet location based on the heat profile at 1146. In some embodiments, selecting the inlet location based on the heat profile includes selecting a plurality of inlet locations. In some embodiments, selecting the inlet location based on the heat profile includes selecting a vertical inlet location. In some embodiments, selecting the inlet location based on the heat profile includes selecting a lateral inlet location. In some embodiments, selecting the inlet location based on the heat profile includes selecting an inlet location at the hottest location on the heat profile. In some embodiments, selecting the outlet location based on the heat profile includes selecting a plurality of outlet locations. In some embodiments, selecting the outlet location based on the heat profile includes selecting a vertical outlet location. In some embodiments, selecting the outlet location based on the heat profile includes selecting a lateral outlet location. In some embodiments, selecting the outlet location based on the heat profile includes selecting an outlet location at the coldest location on the heat profile.

The method 1138 further includes creating a heat sink design having a continuous 3D flow path including a plurality of dissociated unitary cells selecting from the catalog of dissociated unitary cell types, wherein the plurality of dissociated unitary cells includes at least two different dissociated unitary cell types at 1148. For example, the heat sink design may be entirely dissociated unitary cells. In another examples, the heat sink design may include a first portion including the plurality of dissociated unitary cells and a second non-cellular portion. In some embodiments, creating the heat sink design includes directing the 3D flow path in a gradient descent of the heat profile, wherein the 3D flow path directs working fluid from in a direction of less heat on the heat profile.

In some embodiments, the method 1138 includes forming a heat sink based on the heat sink design at 1150. In some embodiments, at least one of the physical dissociated unitary cells is formed prior to assembly of the heat sink, and the physical dissociated unitary cells are welded, adhered, or otherwise bound together. In some embodiments, the heat sink is designed based on a plurality of dissociated unitary cells, and the heat sink is formed as a monolithic element. For example, the heat sink design may include a plurality of dissociated unitary cells, and the heat sink is formed by additive manufacturing (e.g., 3D printing) according to the design. In some embodiments, the plurality of dissociated unitary cells are coupled to a non-cellular frame in the heat sink. For example, the first portion of the heat sink including the plurality of dissociated unitary cells may be formed as a monolithic element, such as by additive manufacturing, and welded, adhered, or otherwise bound to a non-cellular second portion that is machined, cast, or otherwise formed independently of the first portion. In some embodiments, the heat sink design includes both a portion with a plurality of dissociated unitary cells and a non-cellular portion, and the entire heat sink is formed as a monolithic element, such as by additive manufacturing.

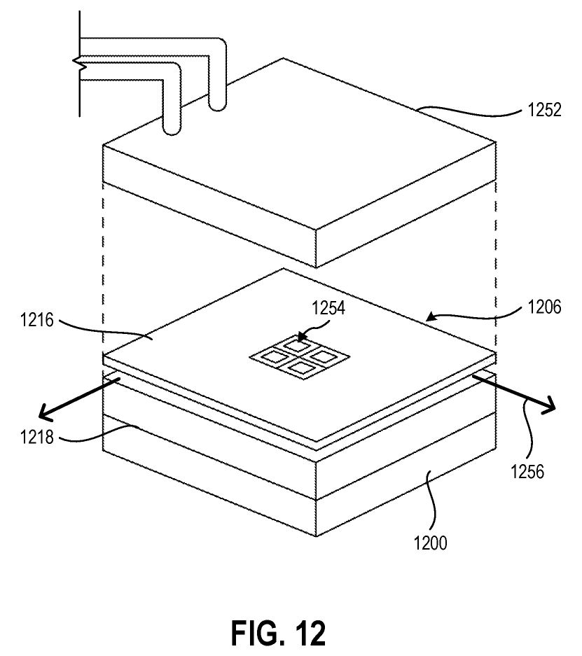

FIG. 12 is a perspective exploded view a heat sink 1206 and manifold 1252 configured to circulate a working fluid through the heat sink 1206, according to at least some embodiments of the present disclosure. In some embodiments, the manifold 1252 receives a stream of cold working fluid from a heat exchanger, chiller, or other cold fluid source and contacts a top surface 1216 of the heat sink 1206. The manifold 1252 directs the cold working fluid to an inlet 1254 of the heat sink 1206. In some embodiments, the inlet 1254 is a vertical inlet. In some embodiments, the inlet 1254 is a lateral inlet.

In some embodiments, the manifold 1252 receives hot working fluid that has passed through the heat sink 1206 and received heat from the computer chip 1200 or other heat-generating electronic component coupled to the base 1218 of the heat sink 1206. In some embodiments, a thermal interface material or other thermally conductive material provides a thermally conductive path from the computer chip 1200 or other heat-generating electronic component to the heat sink 1206. In some embodiments, the manifold receives the hot working fluid from one or more outlets 1256 of the heat sink 1206. In some embodiments, the outlet 1256 is a vertical outlet. In some embodiments, the outlet 1256 is a lateral outlet. In some embodiments, the manifold 1252 does not receive the hot working fluid, and the outlet(s) 1256 exhaust the hot working fluid into an ambient environmental around the heat sink 1206. For example, the heat sink 1206 may be immersed in working fluid, and the manifold 1252 may direct fresh, cold working fluid into the heat sink 1206, while the heat sink 1206 only exhausts the working fluid into a surrounding immersion bath.

The present disclosure relates generally to devices and systems for providing thermal management according to any of the clauses herein:

Clause 1. A heat sink comprising: a plurality of dissociated unitary cells adjacent to one another, wherein each of the dissociated unitary cells includes: a base supporting a body having at least one sidewall, a top surface, and a plurality of fins to direct a cooling fluid through the body in a three-dimensional flow path.

Clause 2. The heat sink of clause 1, wherein at least one dissociated unitary cell of the plurality of dissociated unitary cells includes at least one open side of the body without a sidewall.

Clause 3. The heat sink of clause 1 or 2, wherein at least one dissociated unitary cell of the plurality of dissociated unitary cells directs fluid flow in a straight orientation in a a plane of the heat sink.

Clause 4. The heat sink of any preceding clause, wherein at least one dissociated unitary cell of the plurality of dissociated unitary cells directs fluid flow in a turn orientation in a plane of the heat sink.

Clause 5. The heat sink of any preceding clause, wherein at least one dissociated unitary cell of the plurality of dissociated unitary cells directs fluid flow in a T-junction in a plane of the heat sink.

Clause 6. The heat sink of any preceding clause, wherein at least one dissociated unitary cell of the plurality of dissociated unitary cells directs fluid flow in a downward direction from the top surface toward a base of the at least one of the dissociated unitary cell in a plan view.

Clause 7. The heat sink of any preceding clause, wherein the plurality of fins of at least one dissociated unitary cell of the plurality of dissociated unitary cells includes curved surfaces to promote mixing of the cooling fluid.

Clause 8. The heat sink of any preceding clause, wherein at least one dissociated unitary cell of the plurality of dissociated unitary cells is square in a plane of the heat sink.

Clause 9. The heat sink of any preceding clause, wherein at least one dissociated unitary cell of the plurality of dissociated unitary cells is hexagonal in a plane of the heat sink.

Clause 10. The heat sink of any preceding clause, wherein at least one dissociated unitary cell of the plurality of dissociated unitary cells is triangular in a plane of the heat sink.

Clause 11. The heat sink of any preceding clause, wherein the dissociated unitary cells of the plurality of dissociated unitary cells tesselate.

Clause 12. The heat sink of any preceding clause, further comprising a non-cellular frame in fluid communication with the plurality of dissociated unitary cells to flow a working fluid therebetween.

Clause 13. The heat sink of any preceding clause, wherein the plurality of dissociated unitary cells includes at least two types of dissociated unitary cells.

Clause 14. A thermal management device comprising: a manifold configured to flow a cold working fluid through an inlet into a heat sink according to any preceding clause.

Clause 15. The thermal management device of clause 14, wherein the manifold is configured to receive a hot working fluid from an outlet of the heat sink and circulate the hot working fluid to a heat exchanger or chiller.

Clause 16. The thermal management device of clause 14, wherein the inlet is a lateral inlet into the heat sink.

Clause 17. The thermal management device of clause 14, wherein the inlet is a vertical inlet into the heat sink.

Clause 18. The thermal management device of clause 17, wherein the vertical inlet is in a top surface of a dissociated unitary cell of the plurality of dissociated unitary cells.

Clause 19. The thermal management device of clause 14, wherein the heat sink includes a plurality of inlets.

Clause 20. A method of manufacturing a heat sink, the method comprising: obtaining a heat profile for a multi-component electronic device; obtaining a catalog of dissociated unitary cell types; selecting an inlet location based on the heat profile; selecting an outlet location based on the heat profile; creating a heat sink design having a continuous three-dimensional flow path including a plurality of dissociated unitary cells selected from the catalog of dissociated unitary cell types, wherein the plurality of dissociated unitary cells includes at least two different dissociated unitary cell types; and forming a heat sink based on the heat sink design.

Clause 21. The method of clause 20, wherein the heat sink is any heat sink of claims 1 through 13.

Clause 22. The method of clause 20, wherein the catalog of dissociated unitary cell types includes at least one of a straight orientation unitary cell, a turn unitary cell, a direct impingement unitary cell; a mixing promotion unitary cell; and a T-junction unitary cell.

Clause 23. The method of any of clauses 20 through 22, wherein forming the heat sink includes additive manufacturing the heat sink in a monolithic element.

Clause 24. The method of any of clauses 20 through 22, wherein forming the heat sink includes additive manufacturing a dissociated unitary cell of the plurality of dissociated unitary cells and bonding the dissociated unitary cell to a non-cellular frame.

It should be understood that references to "one embodiment" or "an embodiment" of the present disclosure are not intended to be interpreted as excluding the existence of additional embodiments that also incorporate the recited features. For example, any element described in relation to an embodiment herein may be combinable with any element of any other embodiment described herein, to the extent such features are not described as being mutually exclusive. Numbers, percentages, ratios, or other values stated herein are intended to include that value, and also other values that are "about", "substantially", or "approximately" the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

The terms "approximately," "about," and "substantially" as used herein represent an amount close to the stated amount that is within standard manufacturing or process tolerances, or which still performs a desired function or achieves a desired result. For example, the terms "approximately," "about," and "substantially" may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to "up" and "down" or "above" or "below" are merely descriptive of the relative position or movement of the related elements.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional "means-plus-function" clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words 'means for' appear together with an associated function. Each addition, deletion, and modification to the embodiments that falls within the meaning and scope of the claims is to be embraced by the claims. The described embodiments are therefore to be considered as illustrative and not restrictive, and the scope of the disclosure is indicated by the appended claims rather than by the foregoing description.

What is claimed is:

1. A heat sink comprising:
a plurality of dissociated unitary cells adjacent to one another, wherein each of the dissociated unitary cells includes:
a base supporting a body having at least one sidewall,
a top surface, and
a plurality of fins to direct a cooling fluid through the body in a three-dimensional flow path through the plurality of dissociated unitary cells.

2. The heat sink of claim 1, wherein at least one dissociated unitary cell of the plurality of dissociated unitary cells includes at least one open side of the body without a sidewall.

3. The heat sink of claim 1, wherein at least one dissociated unitary cell of the plurality of dissociated unitary cells directs fluid flow in a straight orientation in a a plane of the heat sink.

4. The heat sink of claim 1, wherein at least one dissociated unitary cell of the plurality of dissociated unitary cells directs fluid flow in a turn orientation in a plane of the heat sink.

5. The heat sink of claim 1, wherein at least one dissociated unitary cell of the plurality of dissociated unitary cells directs fluid flow in a T-junction in a plane of the heat sink.

6. The heat sink of claim 1, wherein at least one dissociated unitary cell of the plurality of dissociated unitary cells directs fluid flow in a downward direction from the top surface toward a base of the at least one of the dissociated unitary cell in a plan view.

7. The heat sink of claim 1, wherein the plurality of fins of at least one dissociated unitary cell of the plurality of dissociated unitary cells includes curved surfaces to promote mixing of the cooling fluid.

8. The heat sink of claim 1, wherein at least one dissociated unitary cell of the plurality of dissociated unitary cells is square in a plane of the heat sink.

9. The heat sink of claim 1, wherein the dissociated unitary cells of the plurality of dissociated unitary cells tesselate.

10. The heat sink of claim 1, further comprising a non-cellular frame in fluid communication with the plurality of dissociated unitary cells to flow a working fluid therebetween.

11. The heat sink of claim 1, wherein the plurality of dissociated unitary cells includes at least two types of dissociated unitary cells.

12. A thermal management device comprising:
a heat sink including:
a plurality of dissociated unitary cells adjacent to one another, wherein each of the dissociated unitary cells includes:
a base supporting a body having at least one sidewall, a top surface, and
a plurality of fins to direct a cooling fluid through the body in a three-dimensional flow path through the plurality of dissociated unitary cells; and
a manifold configured to flow a cold working fluid through an inlet into the heat sink.

13. The thermal management device of claim 12, wherein the manifold is configured to receive a hot working fluid from an outlet of the heat sink and circulate the hot working fluid to a heat exchanger or chiller.

14. The thermal management device of claim 12, wherein the inlet is a lateral inlet into the heat sink.

15. The thermal management device of claim 12, wherein the inlet is a vertical inlet into the heat sink.

16. The thermal management device of claim 15, wherein the vertical inlet is in a top surface of a dissociated unitary cell of the plurality of dissociated unitary cells.

17. The thermal management device of claim 12, wherein the heat sink includes a plurality of inlets.

18. A method of manufacturing a heat sink, the method comprising:
obtaining a heat profile for a multi-component electronic device;
obtaining a catalog of dissociated unitary cell types;
selecting an inlet location based on the heat profile;
selecting an outlet location based on the heat profile;
creating a heat sink design having a continuous three-dimensional flow path including a plurality of dissociated unitary cells selected from the catalog of dissociated unitary cell types, wherein the plurality of dissociated unitary cells includes at least two different dissociated unitary cell types; and
forming a heat sink based on the heat sink design.

19. The method of claim 18, wherein the catalog of dissociated unitary cell types includes at least one of a straight orientation unitary cell, a turn unitary cell, a direct impingement unitary cell; a mixing promotion unitary cell; and a T-junction unitary cell.

20. The method of claim 18, wherein forming the heat sink includes additive manufacturing a dissociated unitary cell of the plurality of dissociated unitary cells and bonding the dissociated unitary cell to a non-cellular frame.
